(19) United States
(12) Patent Application Publication
(10) Pub. No.: US 2026/0350245 A1
(43) Pub. Date: Nov. 5, 2026

(54) METHOD OF GENERATING SHAPE PROFILES OF COMPONENTS IN A COMPUTER-AIDED DESIGN MODEL

(71) Applicant: Siemens Industry Software Inc., Plano, TX (US)

(72) Inventors: David Kennett, Cambridge (GB); Hsu-Wei Huang, Cambridge (GB)

(21) Appl. No.: 19/485,189

(22) PCT Filed: Jun. 5, 2023
(86) PCT No.: PCT/US2023/024423

§ 371 Date: Nov. 17, 2025

(51) Int. Cl. G06F 30/12; G06T 17/20

(52) U.S. Cl. CPC G06F 30/12; G06T 17/20

(57) ABSTRACT

A computer implemented method for generating a vector representation of shape characteristics of a component that forms part of a computer-aided design (CAD) model is provided. The method includes: generating a mesh representation including a plurality of triangular facets; determining a set of points that are quasi-randomly distributed on the mesh; portioning a domain containing the component into a plurality of concentric spheres; identifying a subset of points in each sphere; and determining a vector representation of shape characteristics of the component based on the variance of points along principal axes in each sphere.

The present patent document is a § 371 nationalization of PCT Application Serial No. PCT/US2023/024423, filed Jun. 5, 2023, designating the United States, which is incorporated by reference in its entirety.

### TECHNICAL FIELD

The present disclosure relates to a computer-implemented method for generating shape profiles of components in a computer-aided design (CAD) model.

### BACKGROUND

Computer-Aided Design (CAD) systems are used in many fields of engineering, manufacturing, and design to create and manipulate solid modelling representations of objects. Boundary representation (B-rep) technology dominates CAD modelling. B-rep technology provides an efficient and adaptable representation of parts by combining classic geometry: analytic surfaces and curves, non-uniform rational basis spline (NURBS) and procedural surfaces and curves, with topology, which captures the connectivity and interaction between geometric elements. Additive manufacturing is the process of creating three-dimensional objects using a three-dimensional printer based on CAD or other digital three-dimensional models. Objects may be scanned as a precursor to creating a CAD model, or may be designed from scratch, and stored in either stereolithography file format (STL) or additive manufacturing file format (AMF) for future printing.

As part of the design of an assembly model, a user may choose to create or use components that are the same or similar to other components within the context of the main assembly. Finding components that are an exact match is a relatively simple process; however, this is not necessarily the case for similar components. Similar components are those that share common shape elements with another component. Such common shape elements are component attributes, such as size, geometry, features, function, color, or texture. For example, a user may be designing a vehicle, which requires a nut and bolt assembly to hold two components together. As part of the design process, the user may have already used a similar nut and bolt assembly, and so now wishes to find an appropriate, but similar, nut and bolt pairing in order to complete this aspect of the design.

A user may identify components based on visual similarity, consistent use of naming standards, categorizations, or other classifications, and/or consistent language in order to determine similarity. While this may be a simple task if all of these aspects are present, or there is only a limited number of components in use, as designs become increasingly large or complex, the task becomes increasingly difficult. One possibility is to restrict searches to outside of the CAD application to find a similar component to add to a product. If working within the CAD application, the user may select components within the graphics screen or from a representation of the bill of materials of the components on which the user wishes to operate.

A user may also create sets of components in advance, based on attributes that differentiate whether two components are similar. For example, a user may create sets of bolts, nuts, and screws in advance of working within the CAD application on a product. However, this relies on the user being able to spend time working to select such similar components from large libraries available with CAD software, and that the user is able to predict in advance the range of similarities or uses of components that will be required for modelling various products. One further issue is that the selection is limited by this advance preparation, thus removing the ability to predict and offer alternative similar products to a user during the design process.

A further approach is based on clustering. Clustering is a type of unsupervised machine learning used to categorize or cluster similar data points together. Clustering algorithms discover and analyze patterns or similarities within a dataset, and group the data based on those patterns or characteristics. To apply clustering algorithms in the context of identifying similar components in a CAD model, the components are first given a mathematical description as a numerical vector, referred to herein as a shape profile. Shape profiles are obtained by extracting numerical features of a component so that the object is mapped to a metric space. Mathematical operations may then be applied to the resulting shape profiles.

### SUMMARY

It is an object of the disclosure to provide a method for generating consistent shape profiles for components in CAD models. The scope of the present disclosure is defined solely by the appended claims and is not affected to any degree by the statements within this summary. The present embodiments may obviate one or more of the drawbacks or limitations in the related art.

According to a first aspect, a computer-implemented method for generating a vector representation of shape characteristics of a component that forms part of a computer-aided design (CAD) model is provided. The method includes: a) generating a mesh representation of the component, the mesh representation including a plurality of triangular facets; b) determining a set of points V that are quasi-randomly distributed on the mesh representation; c) partitioning a domain containing the component into a plurality of concentric spheres; d) for each sphere S: i) identifying the subset V_{S}={vⱼ}_{j=1 . . . k} of k points in the set of points V contained in the sphere S; and ii) determining a vector of data values λ_{S}, each data value representing a variance of the points vⱼ along principal axes of the subset V_{S}; and e) combining the vectors λ_{S} to form a vector representation λ of shape characteristics of the component.

The method according to the first aspect achieves the object by providing consistent shape profiles. This is achieved through the use of quasi-randomly distributed points that are scattered across the mesh representation of the component.

According to a second aspect, a computer implemented method for generating a vector representation of shape characteristics of a component that forms part of a computer-aided design (CAD) model is provided. The method includes: a) generating a mesh representation of the component, the mesh representation including a plurality of triangular facets; b) determining a set of points V that are distributed on the mesh representation; c) partitioning a domain containing the component into a plurality of concentric spheres; d) for each sphere S: i) identifying the subset V_{S}={vⱼ}_{j=1 . . . k} of k points in the set of points V contained in the sphere S; and ii) determining a vector of data values λ_{S}, each data value representing a variance of the points vⱼ along principal axes of the subset V_{S}; and e) combining the vectors λ_{S} to form a vector representation λ of shape characteristics of the component, wherein each vector λ_{S} further includes a ratio of the radius of the sphere S to the radius of the outermost sphere.

In a first implementation form, the set of points V includes, for each facet T, a number of points n_{T} lying on the facet T.

In a second implementation form, the number of points n_{T} is:

$${n}_{T} = \frac{{Na}_{T}}{A}$$

where N is the number of points in the set of points V, α_{T} is the area of the facet T, and A is the total area of the plurality of facets.

In a third implementation form, the determining of the set of points V includes, for each facet T: identifying a pair of edge vectors A, B of the facet T; generating a set Q_{T}={(xᵢ, yᵢ), 0≤xᵢ, yᵢ≤1; 1≤i≤n_{T}}, including n_{T} pairs of quasirandom numbers; determining n_{T} quasi-randomly distributed points Pᵢ=A xᵢ+B yᵢ; and when a point Pᵢ is located outside the facet T, reflecting the point in a line corresponding to the vector A−B.

In a fourth implementation form, the pairs of quasi-random numbers are generated from a Halton sequence.

In a fifth implementation form, the determining of the vector of data values λ_{S} for each sphere S includes: determining a covariance matrix C_{S}, where:

$${C}_{s} = \frac{1}{\vert {V}_{s} \vert - 1} {\sum }_{j = 1}^{k} ( {v}_{j} - M ) \cdot {( {v}_{j} - M )}^{T}$$

and

$$M = \frac{1}{k} {\sum }_{j = 1}^{k} {v}_{j}$$

is the balance point of V_{S}; and determining the eigenvalues of the covariance matrix C_{S} to form the vector λ_{S}.

In a sixth implementation form, the partitioning of the domain containing the component into a plurality of concentric spheres includes selecting the radii of the spheres such that points in the set of points V are equidistributed between annuli of successive concentric spheres.

According to a third aspect, a method is provided. The method includes generating vector representations for each of a plurality of components in CAD model, based on the method according to the first aspect, and applying a clustering algorithm to the vector representations of the plurality of components to form one or more clusters of components based on shape similarity.

In an eighth implementation form, the method includes receiving a component selection from a user, via a user interface, the selected component representing shape characteristics desired by the user; and identifying, based on the selection and the one or more clusters, further components having similar shape characteristics to the selected component.

In a ninth implementation form, the method includes performing CAD operations on the identified components.

These and other aspects are apparent from the embodiments described below.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a schematic diagram showing a method of generating a shape profile, according to an example.

FIG. 2 is a diagram of a facet, according to an example.

FIG. 3 is a graphical representation of a distribution of points in three-dimensional space, according to an example.

FIG. 4 is a diagram showing a component in a three-dimensional model, according to an example.

FIGS. 5A and 5B are examples of three-dimensional component datasets with clustering.

FIG. 6 is a flowchart showing the method in accordance with embodiments of the present disclosure.

FIG. 7 illustrates an example of a data processing system in which an embodiment of the present disclosure may be implemented.

### DETAILED DESCRIPTION

Example embodiments are described below in sufficient detail to enable those of ordinary skill in the art to embody and implement the systems and processes herein described. It is important to understand that embodiments may be provided in many alternate forms and should not be construed as limited to the examples set forth herein.

Accordingly, while embodiments may be modified in various ways and take on various alternative forms, specific embodiments thereof are shown in the drawings and described in detail below as examples. There is no intent to limit to the particular forms disclosed. On the contrary, all modifications, equivalents, and alternatives falling within the scope of the appended claims should be included. Elements of the example embodiments are consistently denoted by the same reference numerals throughout the drawings and detailed description where appropriate.

The terminology used herein to describe embodiments is not intended to limit the scope. The articles “a,” “an,” and “the” are singular in that they have a single referent, however the use of the singular form in the present document should not preclude the presence of more than one referent. In other words, elements referred to in the singular may number one or more, unless the context clearly indicates otherwise. The terms “comprises,” “comprising,” “includes,” and/or “including,” when used herein, specify the presence of stated features, items, acts, operations, elements, and/or components, but do not preclude the presence or addition of one or more other features, items, acts, operations, elements, components, and/or groups thereof.

Unless otherwise defined, all terms including technical and scientific terms used herein are to be interpreted as is customary in the art. Terms in common usage should also be interpreted as is customary in the relevant art and not in an idealized or overly formal sense unless expressly so defined herein.

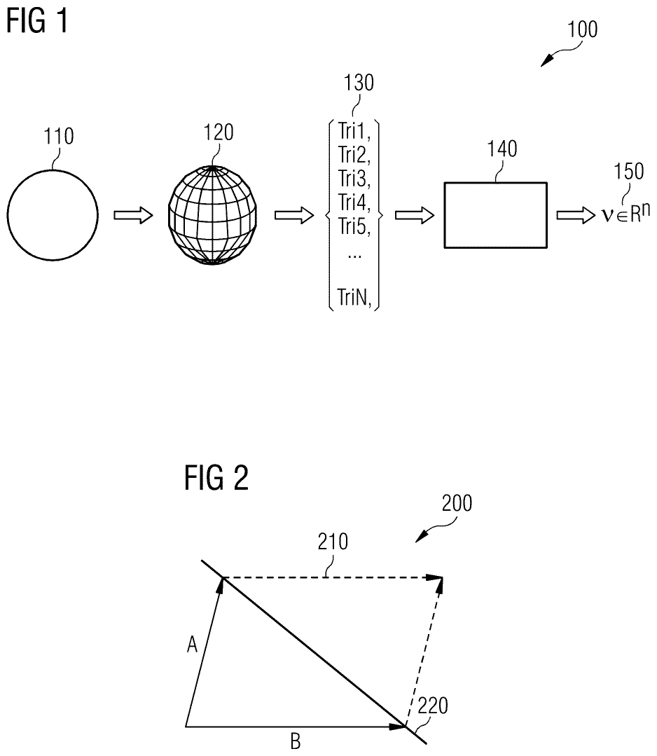

The methods described herein are based on a mapping of a mesh representation of a component to a vector representation to form a shape profile. FIG. 1 shows a schematic diagram of a process for obtaining a vector representation from a component. In FIG. 1, the component is a sphere 110. The surface of sphere 110 is converted to a mesh representation 120 including a plurality of triangular facets. Facet data 130 representing the plurality of triangular facets is converted using a mapping 140 to a vector 150.

The mapping 140 described herein includes two stages. In a first stage, a scattering of points is obtained over the facets of the mesh representation. The scattered points are sufficiently well distributed that high quality consistent shape profiles may be obtained from the points which accurately describe shape characteristics of a component. In a second stage, the space occupied by the shape is partitioned using concentric spheres and values describing the variance of the scattering of points in each sphere are determined. From these values, a vector representation of the shape is obtained.

In the first stage, a well distributed scattering of points may be obtained using quasi-random number sequences. A quasi-random sequence is a deterministic sequence that exhibits some properties of randomness. However, in contrast to random sequences, quasi-random sequences may have a lower discrepancy. Discrepancy quantifies the difference between the expected distribution and the actual distribution of numbers in the sequence. Quasi-random sequences strive to minimize this discrepancy to provide a more regular and evenly spaced distribution. In the context of generating shape profiles, using quasi-random sequences to generate points provide a more regular and evenly spaced distribution of points across the facets.

A Halton sequence is an example of a quasi-random number sequence which may be used to generate scattered points for mapping 140. The Halton sequence may be generated efficiently without a seed input and is straightforward to compute. In particular, values of the Halton sequence are computed from successive divisions of a given base value. For example, for a given base of 2, the first nine elements are as follows: ½, ¼, ¾, ⅛, ⅝, ⅜, ⅞, 1/16, 9/16. Other examples of quasi-random sequences include the Sobol sequence, and the Hammersley sequence.

FIG. 2 shows a schematic diagram of a triangular facet 200, according to an example. The facet 200 has a pair of edge vectors A, B. Any point, P given by the equation P=Ax+By, where 0≤x, y≤1 will be positioned in the parallelogram 210 shown in FIG. 2, which corresponds to the parallelogram determined by the edge vectors of facet 200.

A set of quasi-randomly distributed points may be obtained by generating pairs of quasi-random numbers (x, y), and reflecting any points which lie in the upper triangle of the parallelogram in the line 220 corresponding to the vector A−B. According to an example, x and y may be determined from Halton sequences as previously described, with x being generated using base 2, and y generated using base 3.

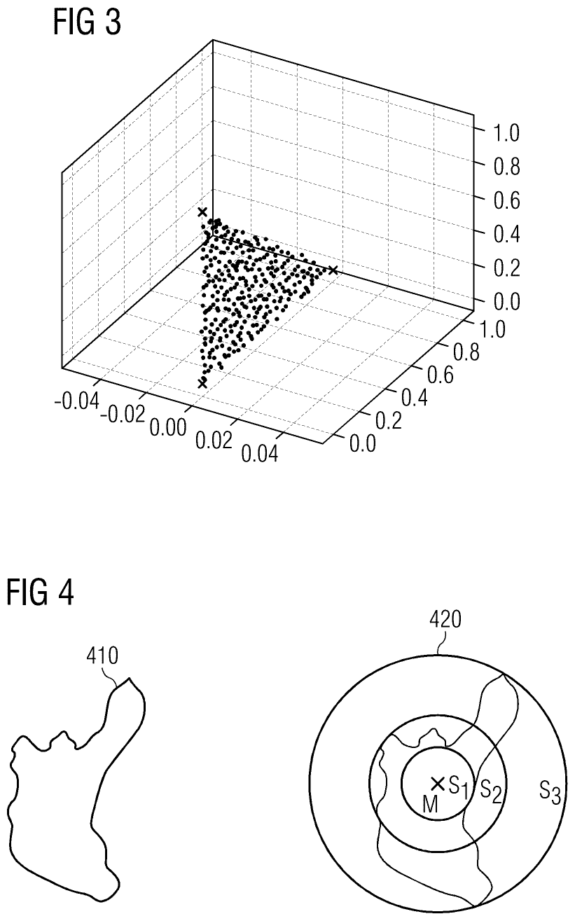

FIG. 3 shows an example of a point scattering over a facet obtained using the method described herein, based on a quasi-random number sequence. As may be observed from FIG. 3, the resulting points are distributed evenly over the surface of the facet.

The number of points per facet may be determined based on the facet's area as a proportion of the total area of all the facets, and the total number of points that are going to be used in the point scattering. In particular, for each facet T the number of points n_{T} allocated to facet T is:

$${n}_{T} = \frac{{Na}_{T}}{A}$$

where N is the total number of points, α_{T} is the area of the facet T and A is the total area of all the facets. For the purpose of the methods described herein, a suitable value of the total number of points may be, for example, N=50,000.

As previously described, the second stage of mapping 140, proceeds by partitioning the domain of the component into a plurality of concentric spheres. FIG. 4 shows an example of a component 410, and a partitioning 420 of a space containing the component into three concentric spheres, S₁, S₂, S₃,

The spheres all center on the same point M referred to herein as the balance point. Denoting the set of N scattered points by V={vⱼ}_{j=1 . . . N}, the balance point M is determined as follows:

$$M = \frac{1}{N} {\sum }_{j = 1}^{N} {v}_{j}$$

The spheres S are selected with radii, such that points are equidistributed between annuli of successive concentric spheres. In other words, in FIG. 4, the number of scattered points between spheres S₁, S₂ is the same as the number of scattered points between spheres S₂, S₃. This provides that the domain is partitioned into areas of equal complexity and therefore is of interest. This may be helpful, for example, to selecting radii such that the spheres are equidistant from each other, as this may lead to some spheres containing very few points. This would lead to points in those spheres having too much influence in the character of the shape profile. Conversely, if there are too many points in a sphere, then it is difficult to extract any meaningful feature from it for the profile.

Points are assigned to each sphere based on a “redundant assignment,” with each sphere containing the points within the spheres that are interior to it too. Then a covariance matrix C_{S} is computed for each sphere:

$${C}_{s} = \frac{1}{\vert {V}_{s} \vert - 1} {\sum }_{j = 1}^{k} ( {v}_{j} - M ) \cdot {( {v}_{j} - M )}^{T}$$

where V_{S}={vⱼ}_{j=1 . . . k} is the subset of points in V in the sphere S, and

$$M = \frac{1}{k} {\sum }_{j = 1}^{k} {v}_{j}$$

is the balance point of V_{S}.

The matrix C_{S} is a 3 by 3 matrix including an outer product of the vector vⱼ−M with itself. An eigensystem of the matrix C_{S} describe how points are scattered in the sphere S. In particular, the eigenvectors correspond to the principal axes of V_{S}, and describe the axes along which the scattering of elements is greatest. The eigenvalues, λ_{S}, of C_{S} describe the variance along the three principal axes and thus may be used to characterize the shape of the elements of V_{S}.

For example, for a thin object like a tube, the eigensystem includes one eigenvector pointing along the shaft of the tube, and two that are perpendicular to this: the eigenvalue for the shaft eigenvector is much larger than for the two vectors that point out of the tube surface. On the other hand, a disc like object has two perpendicular eigenvectors with large eigenvalues that are embedded within the plane of the disc; and a third eigenvector with a much smaller relative eigenvalue pointing normal to the disc. A regular shaped object like a sphere has eigenvectors with identical or near identical eigenvalues.

The eigenvalues λ_{S} are determined for each sphere and are serialized into a vector λ, which forms the shape profile of the component.

According to examples described herein, for each sphere, the vectors λ_{S} may include a ratio of the radius of the sphere S to the radius of the outermost sphere. This adds an extra numerical value per sphere. However, including the ratio does not require any additional normalization operation as the ratio is less than one and may be used in conjunction with the eigenvalues. Furthermore, inclusion of the ratio significantly improves results in subsequent clustering algorithms.

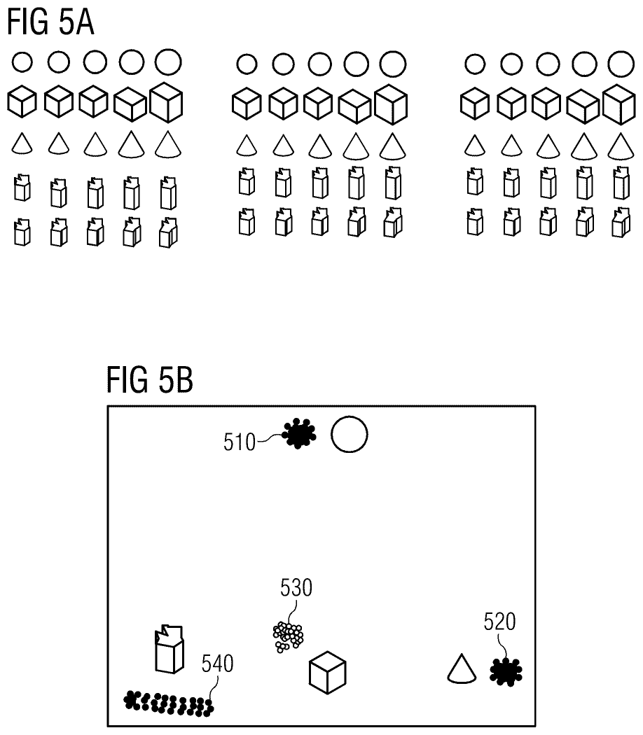

FIGS. 5A and 5B show an example of the application of the methods described herein to perform clustering. FIG. 5A shows a test case that proved difficult to get expected clustering results was with an assembly including 75 parts including 15 spheres, 15 cuboids, 15 cones, and 30 irregular shaped objects.

FIG. 5B shows the result of applying clustering to the shapes using shape profiles generated using the methods described herein. As may be seen from FIG. 5B, the resulting vectors are tightly grouped into clusters 510, 520, 530, 540.

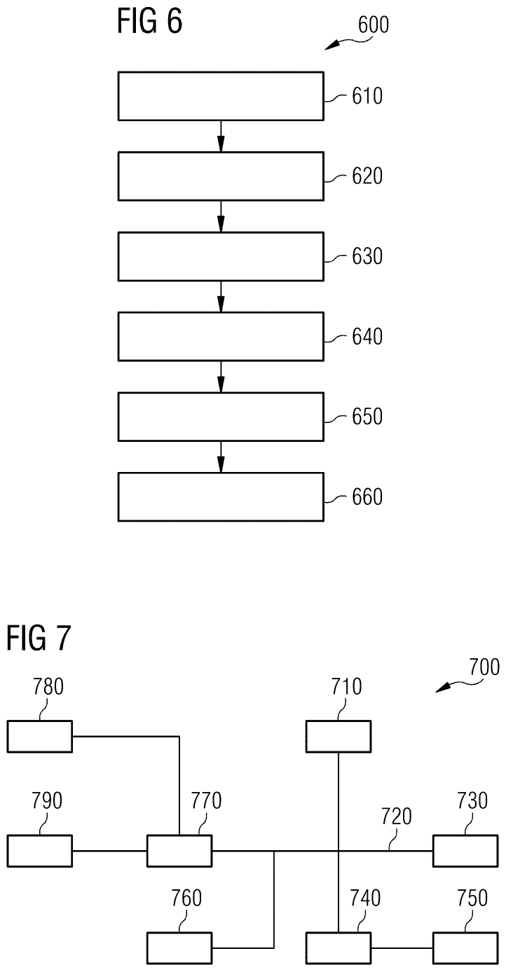

FIG. 6 is a flow diagram showing a computer-implemented method for generating a vector representation of shape characteristics of a component in a CAD model. The method 600 may be implemented in conjunction with examples and other methods and systems described herein. The method 600 may be implemented by a CAD application on a data processing system.

At block 610, the method includes generating a mesh representation of the component. In examples, the mesh representation includes a plurality of triangular facets.

At block 620, the method includes determining a set of points that are quasi-randomly distributed on the mesh representation.

At block 630, the method 600 includes partitioning a domain containing the component into a plurality of concentric spheres.

At block 640, the method includes, identifying for each sphere S, the subset V={vⱼ}_{j=1 . . . k} of k points in the set of points contained in the sphere S.

At block 650, the method 600 includes determining, for each sphere a vector of data values λ_{S}, each data value representing a variance of the points vⱼ along principal axes of the subset V.

At block 660, the method 600 includes combining the vectors λ_{S} to form a vector representation λ of shape characteristics of the component.

The method 600 may also be implemented as part of a manufacturing process for manufacturing an article modelled in a CAD system. In particular, method 600 may be used in conjunction with a clustering algorithm to efficiently identify similar shaped components and perform actions on the identified components prior to manufacturing the article. Examples of actions may include: performing modifications to the article, reporting data relating to components, and communicating data relating to components to a downstream operation.

FIG. 7 illustrates an example of a data processing system in which an embodiment of the present disclosure may be implemented, for example, a CAD application configured to perform the methods of the embodiments as described herein. The data processing system 700 includes a processor 710 connected to a local system bus 720. The local system bus connects the processor to a main memory 730 and graphics display adaptor 740, which may be connected to a display 750. The data processing system may communicate with other systems via a wireless user interface adapter connected to the local system bus 720, or via a wired network, for example, to a local area network. Additional memory 760 may also be connected via the local system bus 720.

A suitable adaptor, such as wireless user interface adapter 770, for other peripheral devices, such as a keyboard 780 and mouse 790, or other pointing device, allows the user to provide input to the data processing system. Other peripheral devices may include one or more I/O controllers such as USB controllers, Bluetooth controllers, and/or dedicated audio controllers (connected to speakers and/or microphones). Various peripherals may be connected to the USB controller (via various USB ports) including input devices (e.g., keyboard, mouse, touch screen, trackball, camera, microphone, scanners), output devices (e.g., printers, speakers), or any other type of device that is operative to provide inputs or receive outputs from the data processing system.

Further, certain devices referred to as input devices or output devices may both provide inputs and receive outputs of communications with the data processing system. Further, other peripheral hardware connected to the I/O controllers may include any type of device, machine, or component that is configured to communicate with a data processing system.

An operating system included in the data processing system enables an output from the system to be displayed to the user on the display and the user to interact with the system. Examples of operating systems that may be used in a data processing system may include Microsoft Windows™, Linux™, UNIX™, iOS™, and Android™ operating systems.

In addition, the data processing system 700 may be implemented as in a networked environment, distributed system environment, virtual machines in a virtual machine architecture, and/or cloud environment. For example, the processor and associated components may correspond to a virtual machine executing in a virtual machine environment of one or more servers. Examples of virtual machine architectures include VMware ESCi, Microsoft Hyper-V, Xen, and KVM.

Those of ordinary skill in the art will appreciate that the hardware depicted for the data processing system 700 may vary for particular implementations. For example, the data processing system 700 in this example may correspond to a computer, workstation, and/or a server. However, alternative embodiments of a data processing system may be configured with corresponding or alternative components such as in the form of a mobile phone, tablet, controller board or any other system that is operative to process data and carry out functionality and features described herein associated with the operation of a data processing system, computer, processor, and/or a controller discussed herein. The depicted example is provided for the purpose of explanation only and is not meant to imply architectural limitations with respect to the present disclosure.

The data processing system 700 may be connected to the network (not a part of data processing system 700), which may be any public or private data processing system network or combination of networks, as known to those of skill in the art, including the Internet. The data processing system 700 may communicate over the network with one or more other data processing systems such as a server (also not part of the data processing system 700). However, an alternative data processing system may correspond to a plurality of data processing systems implemented as part of a distributed system in which processors associated with several data processing systems may be in communication by way of one or more network connections and may collectively perform tasks described as being performed by a single data processing system. Thus, it is to be understood that when referring to a data processing system, such a system may be implemented across several data processing systems organized in a distributed system in communication with each other via a network.

The data processing system 700 is configured to carry out the methods in accordance with the embodiments described herein. For example, the keyboard 780 and mouse 790 may function as a user input device for receiving information from the user, the processor 710 may be configured to carry out the method and the display 750 configured to display a particular view to the user. A computer product including instructions that, when run on a computer, such as the data processing system 700, may be provided to cause the computer to execute the methods of the embodiments of the present disclosure outlined above.

The present disclosure is described with reference to flow charts and/or block diagrams of the method, devices, and systems according to examples of the present disclosure. Although the flow diagrams described above show a specific order of execution, the order of execution may differ from that which is depicted. Blocks described in relation to one flow chart may be combined with those of another flow chart. In some examples, some blocks of the flow diagrams may not be necessary and/or additional blocks may be added.

The present disclosure may be embodied in other specific apparatus and/or methods. The described embodiments are to be considered in all respects as illustrative and not restrictive. In particular, the scope of the disclosure is indicated by the appended claims rather than by the description and figures herein. All changes that come within the meaning and range of equivalency of the claims are to be embraced within their scope.

1. A computer-implemented method for generating a vector representation of shape characteristics of a component that forms part of a computer-aided design (CAD) model, the method comprising:
generating a mesh representation of the component, the mesh representation comprising a plurality of triangular facets;
determining a set of points V that are quasi-randomly distributed on the mesh representation;
partitioning a domain containing the component into a plurality of concentric spheres;
identifying, for each sphere S of the plurality of concentric spheres, a subset V_{S}={vⱼ}_{j=1 . . . k} of k points in the set of points V contained in the respective sphere S;
determining, for each sphere S of the plurality of concentric spheres, a vector of data values λ_{S}, each data value representing a variance of the points vⱼ along principal axes of the respective subset V_{S}; and
combining the vectors λ_{S} to form a vector representation λ of shape characteristics of the component.

2. The method of claim 1, wherein the set of points V comprises, for each facet T, a number of points n_{T} lying on the respective facet T.

3. The method of claim 2, wherein the number of points n_{T} is:
$${n}_{T} = \frac{{Na}_{T}}{A}$$
wherein:
N is the number of points in the set of points V,
α_{T} is an area of the facet T, and
A is a total area of the plurality of triangular facets.

4. The method of claim 2, wherein the determining of the set of points V, comprises, for each facet T:
identifying a pair of edge vectors A, B of the respective facet T;
generating a set Q_{T}={ [symbol] (x [symbol] ᵢ, yᵢ), 0≤xᵢ, yᵢ≤1; 1≤i≤n_{T}}, comprising n_{T} pairs of quasi-random numbers;
determining n_{T} quasi-randomly distributed points Pᵢ=A xᵢ+B yᵢ; and
reflecting a point in a line corresponding to a vector A−B when a point Pᵢ is located outside the respective facet T.

5. The method of claim 4, wherein the pairs of quasi-random numbers are generated from a Halton sequence.

6. The method of claim 1, wherein the determining of the vector of data values λ_{S} for each sphere S comprises:
determining a covariance matrix C_{S}, where:
$${C}_{s} = \frac{1}{\vert {V}_{s} \vert - 1} {\sum }_{j = 1}^{k} ( {v}_{j} - M ) \cdot {( {v}_{j} - M )}^{T} ,$$
wherein
$$M = \frac{1}{N} {\sum }_{j = 1}^{N} {v}_{j}$$
is a balance point of V; and
determining eigenvalues of the covariance matrix C_{S} to form vector λ_{S}.

7. The method of claim 1, wherein the partitioning of the domain containing the component into the plurality of concentric spheres comprises selecting radii of the plurality of concentric spheres such that points in the set of points V are equidistributed between annuli of successive concentric spheres.

8. The method of claim 1, wherein the component comprises a plurality of components,
wherein a vector representation is formed for each component of the plurality of components in the CAD model via the generating of the mesh representation of the respective component, the determining of the set of points, the partitioning of the domain, the identifying of the subset, the determining of the vector, and the combining of the vectors, and
wherein the method further comprises applying a clustering algorithm to the vector representations of the plurality of components to form one or more clusters of components based on shape similarity.

9. The method of claim 8, further comprising:
receiving a component selection from a user, via a user interface, wherein the selected component represents shape characteristics desired by the user; and
identifying, based on the component selection and the one or more clusters, further components having similar shape characteristics to the selected component.

10. The method of claim 9, further comprising:
performing CAD operations on the identified further components.

11. A computer-implemented method for generating a vector representation of shape characteristics of a component that forms part of a computer-aided design (CAD) model, the method comprising:
generating a mesh representation of the component, the mesh representation comprising a plurality of triangular facets;
determining a set of points V that are distributed on the mesh representation;
partitioning a domain containing the component into a plurality of concentric spheres;
identifying, for each sphere S of the plurality of concentric spheres, a subset V_{S}={vⱼ}_{j=1 . . . k} of k points in the set of points V contained in the respective sphere S;
determining, for each sphere S of the plurality of concentric spheres, a vector of data values λ_{S}, each data value representing a variance of the points vⱼ along principal axes of the respective subset V_{S}; and
combining the vectors λ_{S} to form a vector representation λ of shape characteristics of the component,
wherein each vector λ_{S} further comprises a ratio of the radius of the respective sphere S to the radius of an outermost sphere.

12. A data processing system comprising:
a processor configured to:
generate a mesh representation of a component that forms part of a computer-aided design (CAD) model, the mesh representation comprising a plurality of triangular facets;
b) adaption to determine a set of points V that are quasi-randomly distributed on the mesh representation;
partition a domain containing the component into a plurality of concentric spheres;
identify, for each sphere S of the plurality of concentric spheres, a subset V_{S}={vⱼ}_{j=1 . . . k} of k points in the set of points V contained in the respective sphere S; and
determine, for each sphere S of the plurality of concentric spheres, a vector of data values λ_{S}, each data value representing a variance of the points vⱼ along principal axes of the respective subset V_{S}; and
combine the vectors λ_{S} to form a vector representation λ of shape characteristics of the component.

13. The data processing system of claim 12, wherein the processor is further configured to:
apply a clustering algorithm to the vector representation to form one or more clusters of components based on shape similarity.
